(19) United States
(12) Patent Application Publication
(10) Pub. No.: US 2014/0021321 A1
(43) Pub. Date: Jan. 23, 2014

(54) Support Stand

(71) Applicant: Thomas BELLAIR, Glenview, IL (US)

(72) Inventor: Thomas BELLAIR, Glenview, IL (US)

(73) Assignee: JUSTIDEAS COMPANY, Franklin Park, IL (US)

(21) Appl. No.: 13/551,970

(22) Filed: Jul. 18, 2012

(51) Int. Cl. H05K 7/00

(52) U.S. Cl. 248/423

(57) ABSTRACT

A stand for supporting an object, such as a computer monitor. The stand has upper and lower frames that are connected by the side walls of one frame being spaced from each other so that they fit in close proximity to the side walls of the other frame. The upper frame has a platform that bridges or connects downwardly depending generally vertical side walls; while the lower frame has a bottom from which upwardly extending and generally vertical side wall extend. Projections extending inwardly or outwardly from one of the closely side walls of one from engage support edges formed in or carried by a side wall of the other frame. For purposes of cost and appearance, the frames may be made from bent sheets of stainless steel.

### CROSS-REFERENCE TO RELATED APPLICATIONS

This applications claims priority to two earlier U.S. Applications, i.e., Ser. No. 29/404,119, filed Oct. 17, 2011; and Ser. No. 29/404,120, filed Oct. 17, 2011, each of which is incorporated herein by reference in its entirety.

### BACKGROUND

The inventions described herein relate generally to a stand for supporting objects such as computer monitors.

The prior art contains a number of devices for supporting and displaying equipment such as computer monitors. Often these support structures include complex designs containing numerous components. See U.S. Pat. No. 4,560,132; U.S. Pat. No. 4,589,621; U.S. Pat. No. 5,791,259; and U.S. Pat. No. D394,172. A number of prior art designs include injection molded components (e.g., U.S. Pat. No. 6,220,558 and U.S. Pat. No. 6,138,966); while others include fiberboard or actual wood, along with related hardware.

It is desirable for stands of the type used to support computer monitors to be adjustable in height. The prior art includes a number of height-adjustable stands. For example, U.S. Pat. No. D436,760 shows a shelving unit which is freestanding in which the shelves may be positioned at various heights using typical shelf support hardware. A similar design is shown in U.S. Pat. No. D451,306.

It is an objective of the stand disclosed herein to be of relatively simple design and low cost, and yet still be highly stable and adjustable.

### SUMMARY OF THE PREFERRED EMBODIMENTS

The support stands disclosed herein are comprised of two nestable frames, both of which are preferably manufactured from sheet stainless steel. An upper frame includes a platform bridging vertical walls depending from the opposite sides of the frame. Similarly, a base includes two upstanding vertical walls extending from opposite sides of a bottom that is generally planar. When the stand is in an assembled condition, the left side vertical wall of the upper frame is preferably closely adjacent to the left side vertical wall of the lower frame or base; and the same is true of the right side vertical walls of the upper and lower frames. Projections are formed in or otherwise carried by the vertical walls of either the upper frame or the lower frame, and are positioned to align with corresponding support edges formed in or on the vertical walls the other frame. The projections engage supporting edges, and the load carried by the platform of the upper frame is transferred to the lower frame.

In one embodiment, front and rear panels depending from the platform of the upper frame form vertical walls that, together with the side walls, form an open bottom box. The lower frame is an open top box. The side walls are spaces so that at least two of the walls of one of the upper and lower frames will fit closely or nest inside the other. When the frames are assembled, they create an enclosure. Alternatively, in a second embodiment, the front and rear edges of the upper frame contain an upturned lip that prevents objects from sliding off of the platform forwardly and rearwardly. The lower frame does not have front or rear walls. Thus, with this alternative configuration, the space underneath the platform is accessible and usable for storage.

While the embodiments described herein are preferably made of stainless steel, a stand as disclosed herein can be made of a variety of materials including wood and many kinds of plastics. In addition, while the projections are preferably (from a cost standpoint) integrally formed or bent outwardly (or inwardly) from the material of which the frame is made, a separately made and attached (removable or non-removable) projection can be affixed (e.g., by a weld or removeably by a clip) to a vertical wall for engagement with a corresponding support edge on an adjacent wall.

### BRIEF DESCRIPTION OF THE DRAWING FIGURES

FIG. 1 is an exploded perspective view illustrating an embodiment of a stand.

FIGS. 2 through 4 are right side elevational views of an assembled version of the embodiment of FIG. 1 in three height-adjusted positions, respectively.

FIG. 5 is an exploded perspective view illustrating a stand similar to the stand of FIG. 1, but one in which the engaging projections and support edges are reversed; that is, the projections are on the base and the supporting edges are on the upper frame.

FIGS. 6 through 8 are right side elevational views of the stand shown in FIG. 5 depicting the stand in three height-adjusted positions, respectively.

FIG. 9 is a perspective view of a third embodiment of a stand.

FIG. 10 is an enlarged perspective view of the stand shown in FIG. 9 depicting the details of the projections and slots used to hold the upper and lower frames at a predetermined distance from each other.

### DETAILED DESCRIPTION

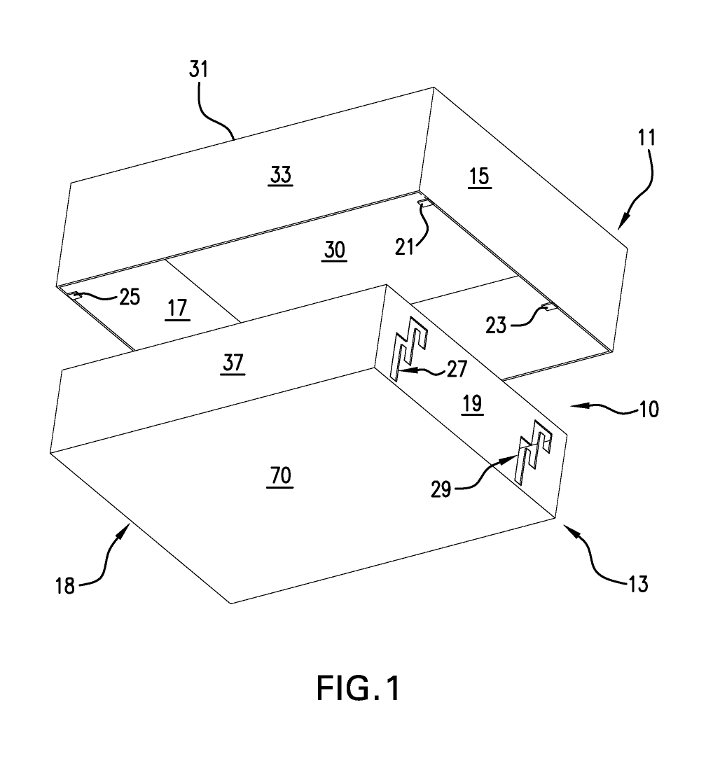

FIG. 1 shows the upper frame 11 exploded with respect to its complementary lower frame 13. The upper frame 11 is comprised of a platform 30, downwardly depending vertical walls 15 and 17 on right and left sides of the platform 30, respectively, and front wall 33 and rear wall 35 depending from the frontend rear edges of the platform 30. Engagement projections in the form of tabs 21 and 23 extend inwardly from the lower edge of the right vertical wall 15. The left vertical wall 17 has corresponding tabs 25 and another tab (not shown). The lower frame 13 or base is constructed in a manner similar to that used to make the upper frame 11. Vertical walls 18 and 19 extend generally perpendicularly upward from a bottom 70 that is preferably generally planar. However, the distance between the vertical wall 19 and the opposite vertical wall 18 is slightly smaller than the distance between the vertical walls 15 and 17 of the upper frame 11. The projections or tabs 21 and 23 fit into the openings 27 and 29, respectively, formed in the vertical wall 19 of the lower frame 13.

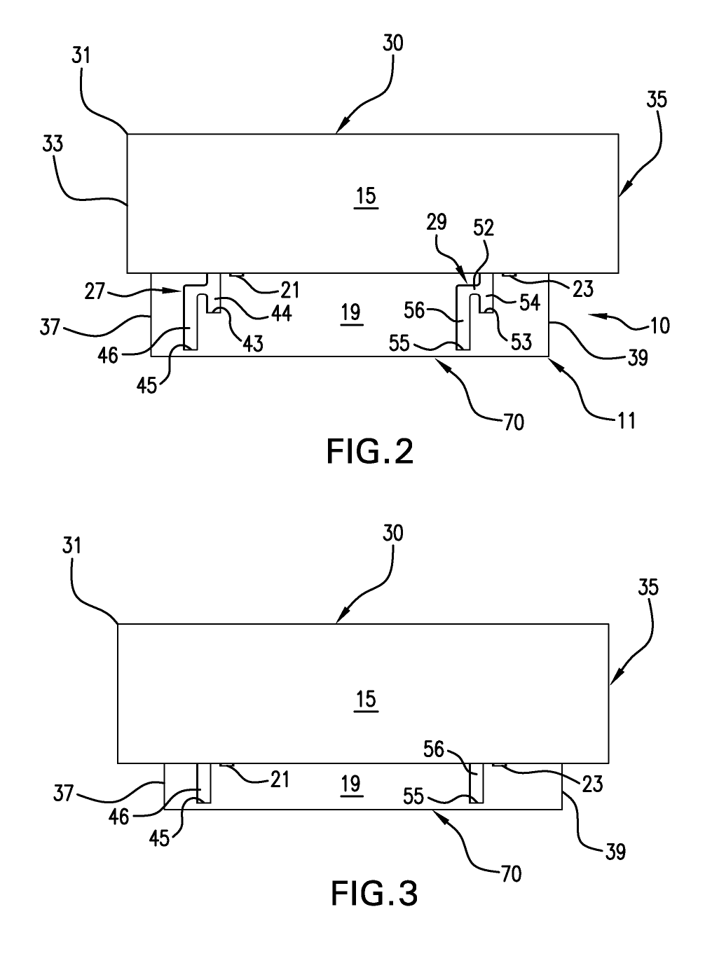

FIGS. 2 through 4 show the upper frame 11 and lower frame 13 in an assembled form, and in various height-adjusted positions. In FIG. 2, the projections or tabs 21 and 23 are resting upon the upper support edges 41 and 51, respectively. In FIG. 2, the configuration of the openings 27 and 29 is shown. Opening 27 includes an upper slot 40 (see FIG. 1), a middle slot 44 and a lower slot 46. Slots 44 and 46 are joined by a connecting slot 42. At the bottom of middle slot 44 is the middle support edge 43, and at the bottom of the lower slot 46 is the lower support edge 45. The rear opening 29 is essentially the same configuration as the front slot 27. The upper slot 50 has at its bottom the upper support edge 51. The middle slot 54 has at its lower end the middle supporting edge 53, and lower slot 56 has support edge 55 at the lower end thereof. In FIG. 3, the engaging projections or tabs 21 and 23 are engaging the corresponding middle support edges 43 and 53, respectively. Finally, FIG. 4 shows the platform 30 in its lowermost position in which the projections or tabs 21 and 23 are extending through the lower slots 46 and 56 and resting against the lower support edges 45 and 55, respectively.

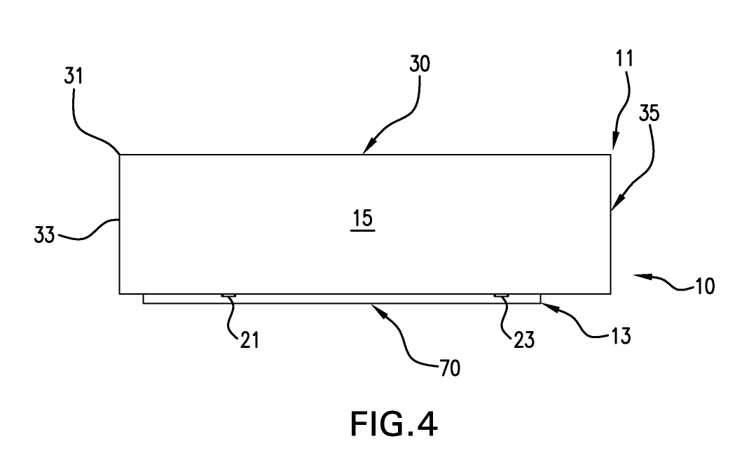

FIG. 5 is an exploded view of an alternative version of a stand 110 comprised of an upper frame 111 and a lower frame 113. In FIG. 5, a prefix “1” has been added to the referenced numerals used in describing the embodiment of FIGS. 1 through 4 to differentiate the components of the embodiment of FIG. 5. However, the second digits of the referenced numerals in FIGS. 5 through 8 correspond to the two-digit referenced numerals used to describe similar parts in FIGS. 1 through 4. Thus, in FIG. 5, the right side wall 115 of the upper frame 111 includes two openings 127 and 129. The forward opening 127 includes three slots 140, 144 and 146, and a connecting slot 142. The projection 121 of the right side wall 119 of the lower frame 130, the opening 127 and engages one of the three supporting edges, 141, 143 and 145. Similarly, the rear projecting tab 123 extending from the upper edge of the vertical wall 119 fits into the opening 129. The tab 123 engages the supporting edge 151, 153 or 155, depending on the desired height of the platform 130 relative to the base or lower frame 113.

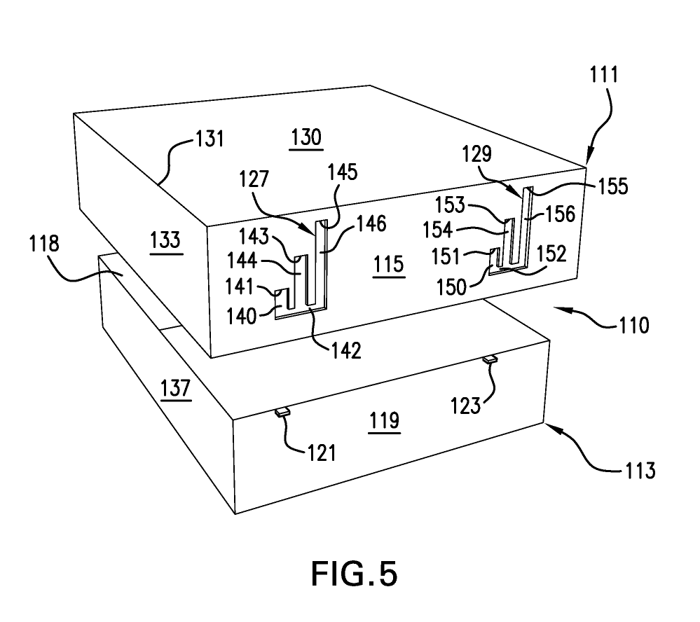

Similar to FIGS. 2-4, FIGS. 6 through 8 show the embodiment of FIG. 5 in three height-adjusted positions, respectively. In FIG. 6, the projecting tab 121 engages the supporting edge 145 and the tab 123 engages the edge 155 when the platform is desired to be in the lowermost position. In FIG. 7, the intermediate position is depicted. In the intermediate position, the tab 121 engages the supporting edge 143, and the tab 123 engages the supporting edge 153. Finally, in FIG. 8, the platform 130 is in its highest adjusted position. In this configuration, the projection or tab 121 is engaging the support edge 141, and the tab 123 is engaging the supporting edge 151.

The upper and lower frames of the embodiments of FIGS. 1 through 8 are generally box-like or parallelepiped-shaped structures. At least two opposing side walls extending upwardly or downwardly are spaced from each other such that at least two pairs of walls on opposite sides of the assemble combination are closely adjacent to each other. The resulting parallelepiped structure is adjustable vertically by changing the positions of the projections of one frame with respect to a series of supporting edges in the other frame.

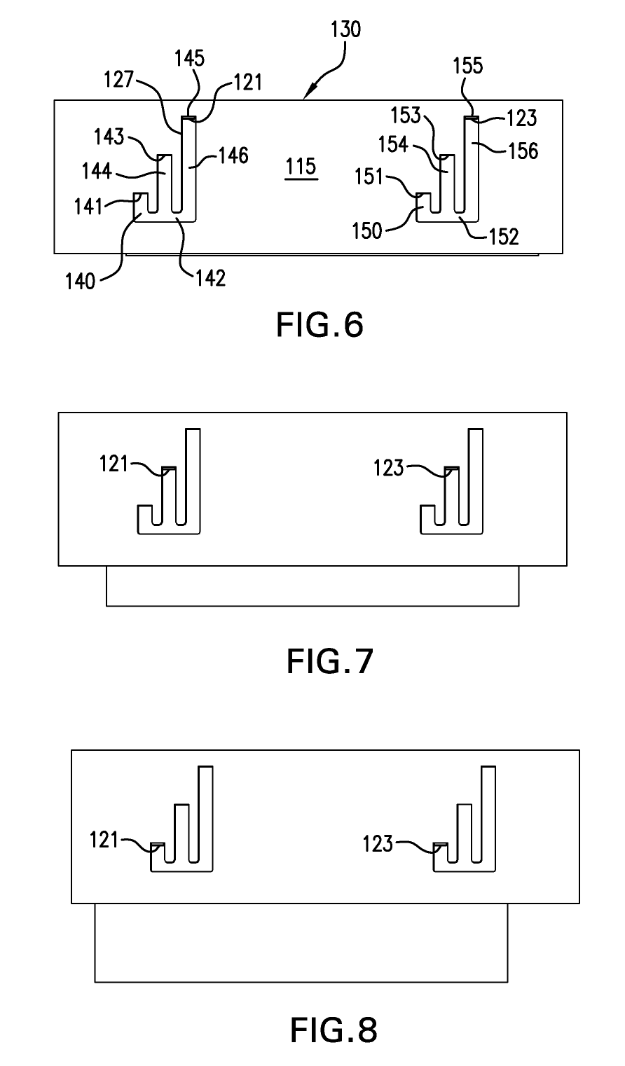

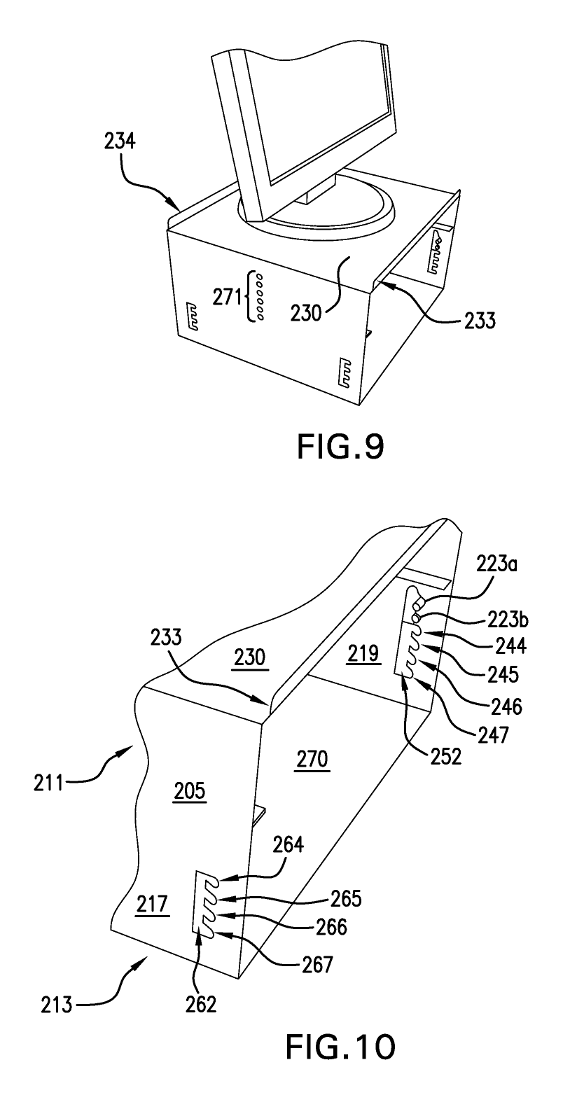

FIGS. 9 and 10 show a third embodiment of a stand. In the embodiment of FIGS. 9 and 10, the upper frame 211 includes a platform 230 and generally vertically disposed sidewalls 205 and 215. In this embodiment, the projections are welded studs supposed on the inside surface of walls 205 and 215. In this example, there are two studs 223a and 223b that engage pairs of adjacent slots in the series of slots which are numbered 240, 243, 244, 245, 246 and 247, which are shown as being vertically aligned, but which may be slanted. A slanted arrangement (like the embodiment of FIGS. 1 through 8), will result in a forward or rearward adjustment of the platform 230 relative to the bottom 270, as the platform is adjusted vertically. The mirror image of this arrangement is present on the vertical wall 217 of the lower frame 213, namely vertically aligned slots 264-267 received a pair of welded studs (not shown) similar to studs 223a and 223b that are affixed to or otherwise carried by the inside surface of the vertical wall 205 of the upper frame 211. The upwardly extending vertical walls 217 and 219 extend from a generally plainer bottom 270 of the lower frame 213.

A distinctive feature of the embodiment of FIGS. 9 and 10 is that the front and rear areas of the stand 210 are open. That is, the platform 230 has a small upwardly extending front lip 233 and a corresponding small upturned lip 235 on the rear edge of the platform 230. The lower frame 213 is without at least a front wall. This allows the space between the upper frame 211 and the lower frame 213 to be used for storage, and that storage space is accessible from the front (and/or the rear if a rear wall is absent from the lower frame 213).

Another feature of the embodiment on FIGS. 9 and 10 is an auxiliary support or locking arrangement comprised of a series of round openings 270 formed in the central portion of the sidewall 205, and a corresponding set of openings (not shown) in sidewall 215. The set of openings 270 (and their corresponding set on the opposite sidewall of the upper frame 211) are engaged by auxiliary studs (not shown) extending outwardly from the vertical walls 217 and 219. This auxiliary engagement provides additional support between the upper frame 211 and the lower frame 213.

The above description of the illustrated embodiments is not intended to be an exhaustive or limiting description of the various possibilities that may occur to persons who have skill in the art upon reading of the foregoing specification. While specific embodiments and examples are described herein for illustrative purposes, various equivalent modifications, alterations or improvements are possible and are intended to be within the scope of the claims appended hereto. The terms used in the following claims should not be construed so as to limit the claimed inventions to the specific embodiments disclosed herein. Rather, the scope of the claims is intended to be determined by the ordinary meaning of the words used in the following claims.

I claim:

1. A stand comprising:
a platform for supporting a device, such as a computer monitor,
a first set of at least two generally vertical sections depending generally perpendicularly from the platform,
a base with a second set of at least two generally vertical sections,
the first and second sets of vertical sections being generally parallel and the at least one vertical section of one set being generally adjacent to at least one vertical section of the other set when the base and platform are in an assembled condition,
at least one of the sets of vertical sections comprising at least one projection extending from a vertical section of the one set, and another of the sets of vertical sections comprising at least one supporting edge carried by the another of the sets for engaging the at least one projection, whereby engagement of the at least one projection by the at least one supporting edge tends to hold the platform a predetermined distance from the base.

2. A stand according to claim 1 further comprising:
the platform and base, and their respective vertical walls, each being made of sheets of stainless steel.

3. A stand according to claim 1 further comprising:
the first set of vertical sections comprising at least two projections on each vertical section, the projections being in the form of tabs extending inwardly from lower ends of the vertical sections.

4. A stand according to claim 3 further comprising;
the second set of vertical sections comprising at least two openings in each of the vertical sections of the second set, each of the openings including a plurality of supporting edges,
the tabs on the first set of vertical sections being located on the vertical sections of the first set such that placement of one tab onto a supporting edge of the vertical sections of the second set will allow at least three tabs to align with and engage at least three corresponding supporting edges.

5. A stand according to claim 1 further comprising;
the platform being generally rectangular, the first set of vertical sections depending from the left and right sides of the rectangular platform, and upturned ledges being formed at front and rear sides of the rectangular platform.

6. A stand according to claim 5 further comprising:
the base being generally rectangular, the second set of vertical sections extending from the left and right sides of the rectangular base,
in an assembled condition, the platform and base forming a generally parallelepiped-shaped box with at least one of the front and rear sides being generally open to allow placement of items inside the box for purposes of storing the items.

7. A stand according to claim 4 further comprising:
each of the vertical sections of the base comprising front and rear sets of supporting edges, the supporting edges being formed at the ends of corresponding set of slots, and the slots being formed in the vertical sections and being joined by openings that connect the slots of a set of slots, whereby the height of the platform relative to the base may be adjusted by moving the projections within the slots and the openings without disassembling the platform and the base.

8. A stand according to claim 1 further comprising:
the at least one projection being carried at least one of the vertical sections of the first set, and being a tab integrally formed therewith.

9. A stand according to claim 1 further comprising:
the at least one projection being carried at least one of the vertical sections of the first set, and being non-removeably attached thereto.

10. A stand according to claim 1 further comprising:
the at least one projection being carried at least one of the vertical sections of the first set, and a separate component removeably attached to at least one of the vertical sections of the first set.

11. A stand for supporting an object relative to a surface, the stand comprising:
first and second frames,
each frame comprising at least two generally parallel vertical sections,
at least one of the frames comprising a platform connecting the vertical sections thereof,
each of the vertical sections of each of the frames comprising an engagement structure selected from the group consisting of a supporting edge and a supporting projection,
each of at least two of the vertical sections of one of the frames being adjacent to a vertical section of another one of the frames, such that a supporting projection engages a supporting edge to hold the platform a predetermined distance from the surface.

12. A stand according to claim 11 further comprising:
the platform and base being made of bent sheets of stainless steel.

13. A stand according to claim 12 further comprising:
the first set of vertical sections comprising at least two projections on each vertical section, the projections being in the form of tabs bent inwardly from lower portions of the vertical sections, and
the second set of vertical sections comprising at least two openings in each of the vertical sections of the second set, each of the openings including a plurality of supporting edges,
the tabs on the first set of vertical sections being located on the vertical sections of the first set such that placement of one tab onto a supporting edge of the vertical sections of the second set will allow at least three tabs to align with and engage at least three corresponding supporting edges.

15. A stand according to claim 11 further comprising;
the platform being generally rectangular, the first set of vertical sections depending from the left and right sides of the rectangular platform, and upturned ledges being formed at front and rear sides of the rectangular platform, and
the base being generally rectangular, the second set of vertical sections extending from the left and right sides of the rectangular base,
in an assembled condition, the platform and base forming a generally parallelepiped-shaped box with at least one of the front and rear sides being generally open to allow placement of items inside the box for purposes of storing the items, and
each of the vertical sections of the base comprising front and rear sets of supporting edges, the supporting edges being formed at the ends of corresponding set of slots, and the slots being formed in the vertical sections and being joined by openings that connect the slots of a set of slots, whereby the height of the platform relative to the base may be adjusted by moving the projections within the slots and the openings without disassembling the platform and the base.

16. A stand according to claim 1 further comprising:
the at least one projection being carried at least one of the vertical sections of the first set, and being selected from the group consisting of: a tab integrally formed with at least one of the vertical sections, a tab non-removeably attached to at least one of the vertical sections, and a separate component removeably attached to at least one of the vertical sections.

17. A stand according to claim 11 further comprising:
the platform being generally rectangular, the first set of vertical sections depending from the left and right sides of the rectangular platform, and upturned ledges being formed at front and rear sides of the rectangular platform, and
the base being generally rectangular, the second set of vertical sections extending from the left and right sides of the rectangular base,
in an assembled condition, the platform and base forming a generally parallelepiped-shaped box with at least one of the front and rear sides being generally open to allow placement of items inside the box for purposes of storing the items, and
the at least one projection being carried by the base, and the at least one supporting edge being carried by the platform,
each of the vertical sections of the platform comprising front and rear sets of supporting edges, the supporting edges being formed at the ends of corresponding set of slots, and the slots being formed in the vertical sections and being joined by openings that connect the slots of a set of slots, whereby the height of the platform relative to the base may be adjusted by moving the projections within the slots and the openings without disassembling the platform and the base.

18. A stand comprising:
a platform for supporting a device, such as a computer monitor,
the platform being comprising a generally rectangular bridge and two downwardly depending vertical walls extending from sides of the bridge, the bridge comprising front and rear edges with upturned edges,
a base being comprised of a generally rectangular bottom and generally vertical walls extending upwardly from left and right sides of the bottom,
the vertical walls of the platform being spaced from each other and the vertical walls of the base being spaced from each other such that the walls of the base fit adjacent to the walls of the platform,
the vertical walls comprising a plurality of cooperating supporting edges and a plurality of projections, whereby engagement between the projections and the supporting edges holds the platform a predetermined distance from the base,
the platform and the base each being formed of a single sheet of metal, and the vertical walls of one of the base and platform fitting inside the vertical walls of the other of the base and platform.

19. A stand according to claim 18 further comprising:
the base and platform forming a parallelepiped-shaped box when the projections and supporting edges are in engagement, at least one of the front and rear of the parallelepiped-shaped box being open and generally unobstructed by a vertical wall, such that the interior of the parallelepiped-shaped box provides a storage space.

20. A stand according to claim 18 further comprising:
at least one upturned edge on one of a front and rear edge of the platform, whereby sliding of objects forwardly or rearwardly from the platform is restricted.
